(19) United States
(12) Patent Application Publication
(10) Pub. No.: US 2011/0025579 A1
(43) Pub. Date: Feb. 3, 2011

(54) SEMICONDUCTOR DEVICE, AND RADIO FREQUENCY SWITCH AND RADIO FREQUENCY MODULE USING THE SEMICONDUCTOR DEVICE

(75) Inventors: Hiroaki KAWANO, Osaka (JP); Masahiko INAMORI, Osaka (JP); Shinichi SONETAKA, Osaka (JP); Junji KAIDO, Osaka (JP)

Correspondence Address: GREENBLUM & BERNSTEIN, P.L.C., 1950 ROLAND CLARKE PLACE, RESTON, VA, 20191, US

(73) Assignee: PANASONIC CORPORATION, Osaka (JP)

(21) Appl. No.: 12/840,789

(22) Filed: Jul. 21, 2010

(30) Foreign Application Priority Data
Jul. 28, 2009 (JP) 2009-175920

(51) Int. Cl. H01Q 9/04; H01L 29/772

(52) U.S. Cl. 343/860; 257/252; 257/E29.242

(57) ABSTRACT

A semiconductor device which detects a power level of a radio-frequency signal includes: a switch FET including: a semiconductor layer; a source electrode and a drain electrode; a first gate electrode; a second gate electrode formed between the first gate electrode and the drain electrode and on the semiconductor layer, each of the first gate electrode and the second gate electrode being in Schottky contact with the semiconductor layer, and the source electrode receiving the radio-frequency signal; a resistor having one end electrically connected to the first gate electrode and an other end electrically connected to the drain electrode via a capacitor; and a power detection terminal electrically connected to a connecting point between the resistor and the capacitor.

### BACKGROUND OF THE INVENTION

(1) Field of the Invention

The present invention relates to a device which is used mainly in mobile communication equipment and the like and which detects a power level of a radio-frequency (RF) signal.

(2) Description of the Related Art

Mobile communication equipment such as mobile phones control transmission power according to a distance from a base station or the like in view of the efficiency of electric wave use and power consumption. The transmission power is generally controlled by adjusting gain of a radio-frequency power amplifier that is mounted on a radio frequency front end module (radio frequency module). In the radio-frequency power amplifier, output power level and efficiency change according to an impedance of an output matching circuit. In theory, the maximum output power level and the maximum efficiency cannot be obtained at the same time with a single impedance. The impedance of the output matching circuit is designed generally so that the maximum efficiency is obtained when the transmission power level is at the maximum. Accordingly, the efficiency decreases when the transmission power level is low. There is therefore a well-known technique that improves efficiency when the output power level is low, by detecting an output power level and controlling the impedance of the output matching circuit according to the power level (see Patent Reference 1: Japanese Unexamined Patent Application Publication No. 2005-528001, for example).

### SUMMARY OF THE INVENTION

FIG. 10 shows a block diagram of a configuration example of a radio frequency module to which the above-described technique is applied. It is to be noted that a radio frequency module including a single transmitting path and a single receiving path is exemplified for simplification in FIG. 10, however, the operating principle described below is the same also in the case where more than two paths are included.

The radio frequency module in FIG. 10 includes: a transmission baseband unit 200; a reception baseband unit 201; a radio-frequency power amplifier 202; an output matching circuit 203; a power detection circuit 204; a radio frequency switch 205; an antenna 206; and a control circuit 207.

In this radio frequency module, an RF signal modulated by the transmission baseband unit 200 is power-amplified by the radio-frequency power amplifier 202, and then emitted from the antenna 206 via the output matching circuit 203 and the radio frequency switch 205. Furthermore, since the power level of the RF signal is detected by the power detection circuit 204 and the impedance of the output matching circuit 203 is optimized by the control circuit 207 according to the power level as described above, it is possible to obtain high efficiency in a broad output power range. It is to be noted that the control circuit 207 generates a control signal for varying the impedance of the output matching circuit 203 according to the power level of the RF signal. Furthermore, the radio frequency switch 205 is used for switching between the transmitting path and the receiving path.

In the detection circuit of the output power level (power detection circuit 204), a half-wave rectifier circuit that uses rectifying property of a diode is widely used because the half-wave rectifier circuit has a simple circuit configuration and can implement a relatively fine detection sensitivity. FIG. 11 shows a circuit diagram of the power detection circuit 204 that uses the half-wave rectifier circuit.

The power detection circuit 204 is loaded into an RF signal path, that is, an RF signal path 302 that connects an input terminal 300 and an output terminal 301, and includes: a power detection terminal 303; a diode 304; a resistor 305; a DC cut capacitor 306; a smooth capacitor 307; an earth terminal 308.

In the radio frequency module having the above-described configuration, an RF signal that has been power-amplified by the radio-frequency power amplifier 202 is received by the input terminal 300 and output through the output terminal 301 to which the radio frequency switch 205 and the antenna 206 are connected. At this time, the diode 304 is in a conduction state when the voltage value of the RF signal that has been applied is greater than a rise voltage of the diode 304, and is in a blocking state when the voltage value of the RF signal is smaller than the rise voltage of the diode 304. Accordingly, when an RF signal having a waveform illustrated in FIG. 12A is applied, the power detection terminal 303 is provided with a detection signal; that is, a detection signal having the waveform illustrated in FIG. 12B, obtained by performing half-wave rectification on an input signal; that is, the RF signal that has been applied, according to discharge and charge of the smooth capacitor 307, and a signal that reflects the power level of the input signal is detected using the time integral.

It is to be noted that the DC cut capacitor 306 is mounted so as to block the DC bias of the RF signal path 302 and the DC bias of the diode 304. In addition, the smooth capacitor 307 is not necessarily needed, however, mounted in some cases so as to smooth the detection signal provided to the power detection terminal 303.

FIG. 12C shows a waveform of a detection signal in the case where the smooth capacitor 307 is not mounted. Although the smoothness of the detection signal is impaired, the power level of the RF signal can be detected using the time integral of the detection signal in the same manner as in the case where the smooth capacitor 307 is mounted.

The radio frequency module shown in FIG. 10 and FIG. 11 has the following problems: a problem in that a part of the RF signal leaks to the earth terminal 308 via the power detection circuit 204 when the power detection circuit 204 that has the configuration described above is added to the RF signal path 302, leading to an increase in insertion loss; and a problem in that harmonic distortion occurs due to nonlinearity of the current-voltage characteristics of the diode 304.

An object of the present invention is, in view of the foregoing, to provide a semiconductor device which detects a power level of an RF signal with a low insertion loss and low distortion characteristics, and to a radio frequency switch and a radio frequency module which use the semiconductor device.

In order to solve the above described problem, the semiconductor device according to an aspect of the present invention is a semiconductor device which detects a power level of a radio-frequency signal, the semiconductor device including: a first FET including: a semiconductor layer; a source electrode and a drain electrode that are formed on the semiconductor layer; a first gate electrode formed between the source electrode and the drain electrode and on the semiconductor layer; and a second gate electrode formed between the first gate electrode and the drain electrode and on the semiconductor layer, each of the first gate electrode and the second gate electrode being in Schottky contact with the semiconductor layer, and the source electrode receiving the radio-frequency signal; a resistor having one end electrically connected to the first gate electrode and an other end electrically connected to the drain electrode via a capacitor; and a power detection terminal electrically connected to a connecting point between the resistor and the capacitor.

With the above configuration, since the power level of the input signal is detected by feeding back a part of the RF signal that has been applied, there is practically no signal leakage to the earth terminal, and thus an insertion loss is improved. In addition, since the power level can be detected without using a diode, distortion characteristics are improved. As a result, it is possible to implement a semiconductor device that detects the power level of an RF signal with a low insertion loss and low distortion characteristics.

Furthermore, another aspect of the present invention can be implemented as a semiconductor device which detects a power level of a radio-frequency, the semiconductor device including: a first FET including: a semiconductor layer; a source electrode and a drain electrode that are formed on the semiconductor layer; a first gate electrode formed between the source electrode and the drain electrode and on the semiconductor layer; and a second gate electrode formed between the first gate electrode and the drain electrode and on the semiconductor layer, each of the first gate electrode and the second gate electrode being in Schottky contact with the semiconductor layer, and the source electrode receiving the radio-frequency signal; a resistor having one end electrically connected to the second gate electrode and an other end electrically connected to the source electrode via a capacitor; and a power detection terminal electrically connected to a connecting point between the resistor and the capacitor.

With the above configuration, since the power level of the input signal is detected by feeding forward a part of the RF signal that has been applied, there is practically no signal leakage to the earth terminal, and thus an insertion loss is improved. In addition, since the power level can be detected without using a diode, so distortion characteristics are improved. As a result, it is possible to implement a semiconductor device that detects the power level of an RF signal with a low insertion loss and low distortion characteristics.

Furthermore, another aspect of the present invention can be implemented as a radio frequency switch including: the semiconductor device; a first terminal electrically connected to the source electrode, through which a radio-frequency signal is input; a second terminal electrically connected to the drain electrode via a second FET, and through which the radio-frequency signal is output; and a third terminal electrically connected to a connecting point between the first FET and the second FET, and through which the radio-frequency signal is input and the radio-frequency signal that has been input is output.

Furthermore, another aspect of the present invention can be implemented as a radio frequency module including: the radio frequency switch; an amplifier electrically connected to the first terminal via an output matching circuit, the amplifier supplying the first terminal with a radio-frequency signal that is amplified; an antenna electrically connected to the second terminal, the antenna transmitting and receiving the radio-frequency signal; and a control circuit that controls an impedance of the output matching circuit according to a potential of the power detection terminal.

With the above configuration, it is possible to implement a radio frequency module with a low insertion loss and low distortion characteristics. In addition, since the radio frequency switch has a function of detecting the power level of an input signal, it is possible to reduce the size of a chip and lower the costs compared to the case where a power detection circuit is separately provided in a radio frequency module.

According to the present invention, it is possible to provide a power detection circuit with a low insertion loss and low distortion characteristics, and a radio frequency switch and a radio frequency module which use the power detection circuit.

### FURTHER INFORMATION ABOUT TECHNICAL BACKGROUND TO THIS APPLICATION

The disclosure of Japanese Patent Application No. 2009-175920 filed on Jul. 28, 2009 including specification, drawings and claims is incorporated herein by reference in its entirety.

### BRIEF DESCRIPTION OF THE DRAWINGS

These and other objects, advantages and features of the invention will become apparent from the following description thereof taken in conjunction with the accompanying drawings that illustrate a specific embodiment of the invention. In the Drawings:

FIG. 1 is a block diagram which illustrates, as an example, a configuration of a radio frequency module according to an embodiment of the present invention;

FIG. 2 is a circuit diagram which illustrates, as an example, a configuration of a radio frequency switch according to Example 1;

FIG. 3 is a sectional view which shows a configuration of a power, detection circuit according to Example 1;

FIG. 4A is a diagram which illustrates, as an example, a waveform of an input signal supplied to the power detection circuit;

FIG. 4B is a diagram which illustrates, as an example, a waveform of an output signal provided to a power detection terminal of the power detection circuit;

FIG. 5 is a diagram which shows insertion losses of: a radio frequency module according to a conventional technique; and a radio frequency module that includes the radio frequency switch according to Example 1;

FIG. 6 is a sectional view which shows a configuration of a power detection circuit according to Example 2;

FIG. 7 is a sectional view which shows a configuration of a power detection circuit according to Example 3;

FIG. 8A is a diagram which shows second-order harmonic distortion of a radio frequency switch according to a conventional technique and a radio frequency switch according to Examples 1 and 3;

FIG. 8B is a diagram which shows third-order harmonic distortion of a radio frequency switch according to a conventional technique and a radio frequency switch according to Examples 1 and 3;

FIG. 9 is a sectional view which shows a configuration of a power detection circuit according to Example 4;

FIG. 10 is a block diagram which illustrates, as an example, a configuration of a conventional radio frequency module;

FIG. 11 is a circuit diagram which illustrates, as an example, a conventional power detection circuit;

FIG. 12A is a diagram which illustrates, as an example, a waveform of an input signal supplied to the power detection circuit;

FIG. 12B is a diagram which illustrates, as an example, a waveform of an output signal provided to a power detection terminal of the power detection circuit; and

FIG. 12C is a diagram which illustrates, as an example, a waveform of a detection signal provided to the power detection terminal of the power detection circuit in the case where a smooth capacitor is not mounted.

### DESCRIPTION OF THE PREFERRED EMBODIMENTS

The following describes some examples related to the best mode for carrying out the present invention, with reference to the drawings.

It is to be noted that, in the diagrams, the same numerals are assigned to the elements which represents substantially the same configuration, operation, and effect. Furthermore, the numerical values described below are provided as examples for specifically explaining the present invention and the present invention is not limited to the numerical values that have been exemplified. Furthermore, the connection relationships between the components are provided as examples for specifically explaining the present invention and the connection relationships for implementing the functions of the present invention are not limited to this. Furthermore, although there is no particular limitation, the present invention is especially preferable in an apparatus which detects the power level of an RF signal and which is formed on: a silicon on insulator (SOI) semiconductor substrate; or a compound semiconductor substrate such as the gallium arsenide substrate. In addition, the FET included in the present invention may be any type of FET as long as the FET has a rectifying property between a gate electrode and a source electrode, or between a gate electrode and a drain electrode, such as a high electron mobility transistor (HEMT), a metal semiconductor FET (MESFET), or a junction FET (JFET). Furthermore, the source electrode and the drain electrode of the FET have the same structure and function in most cases and they are not clearly distinguished in many cases, however, in the following description, the electrode to which a signal is applied is described as a source electrode and the electrode through which a signal is output is described as a drain electrode, for convenience.

Many radio frequency modules, in general, include a radio frequency switch for selecting a signal path according to the difference between transmission and reception, or to a frequency band or a communication mode of a current communication. The radio frequency module according to the present embodiment has an essential point in that a function to detect the power level of an input signal is added to the radio frequency switch.

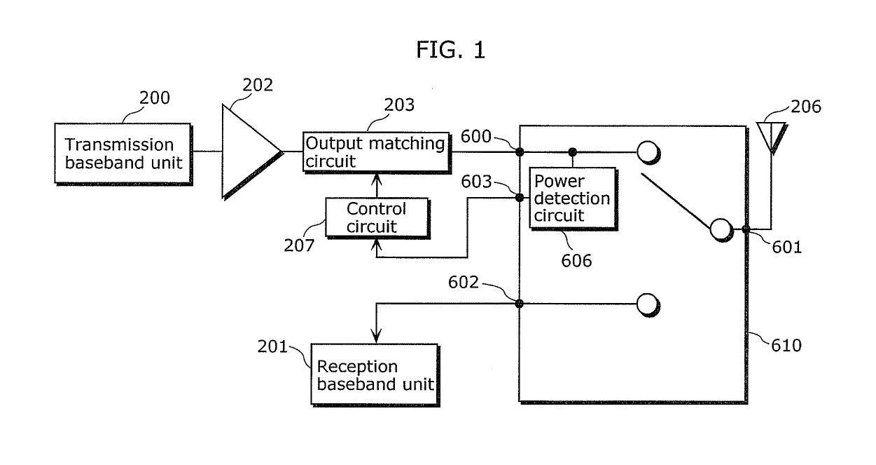

FIG. 1 is a block diagram which illustrates, as an example, a configuration of a radio frequency module according to the present embodiment. It is to be noted that the radio frequency module including a single transmitting path and a single receiving path is provided as an example for simplification in FIG. 1, however, the configuration diagram is the same also in the case where more than two paths are included.

The radio frequency module includes: a transmission baseband unit 200; a reception baseband unit 201; a radio-frequency power amplifier 202; an output matching circuit 203; a radio frequency switch 610 having a power detection circuit 606; an antenna 206; and a control circuit 207.

The radio frequency switch 610 includes: an input terminal 600 to which an RF signal is applied from the output matching circuit 203; a power detection terminal 603 for providing the control circuit 207 with a detection signal received from the power detection circuit 606; an output terminal 602 for providing the reception baseband unit 201 with an RF signal received by the antenna 206; and an input and output terminal 601 for providing the antenna 206 with the radio frequency signal applied to the input terminal 600 and for receiving the RF signal from the antenna 206.

The radio frequency switch 610 serves as a switch that switches between transmission and reception of an RF signal, electrically connects the input terminal 600 and the input and output terminal 601 at the time of transmission, and electrically connects the output terminal 602 and the input and output terminal 601 at the time of reception.

The reception baseband unit 201 is electrically connected to the output terminal 602.

The radio-frequency power amplifier 202 is electrically connected to the input terminal 600 via the output matching circuit 203, amplifies the RF signal provided from the transmission baseband unit 200, and supplies the input terminal 600 with the RF signal that has been amplified.

The antenna 206 is electrically connected to the input and output terminal 601 and transmits and receives the RF signal.

The control circuit 207 is electrically connected to the power detection terminal 603 and controls an impedance of the output matching circuit 203 according to a detection signal; that is, a potential of the power detection terminal 603.

The power detection circuit 606 is an example of the semiconductor device according to the present invention which has a function of detecting power of an RF signal, and included in the radio frequency switch 610. The power detection circuit 606 detects the power level of the RF signal that has been transmitted, by feeding back or feeding forward a part of the RF signal and indicates the detected power level using a potential of the power detection terminal 603.

With the radio frequency module according to the present embodiment as described above, the power detection circuit 606 included in the radio frequency switch 610 detects a power level by feeding back or feeding forward a part of an RF signal, and thus little or no signal leakage occurs to the earth terminal via the power detection circuit. As a result, it is possible to implement a radio frequency module with a low insertion loss

Furthermore, with the radio frequency module according to the present embodiment, the power detection circuit 606 included in the radio frequency switch 610 detects the power level without using a diode. As a result, it is possible to implement a radio frequency module with low distortion characteristics.

Furthermore, in the radio frequency module according to the present embodiment, the power detection circuit 606 included in the radio frequency switch 610 is compact. As a result, it is possible to obtain additional effects of a reduced chip size and reduced costs accordingly, compared to the case where the power detection circuit 606 is separately added.

### Example 1

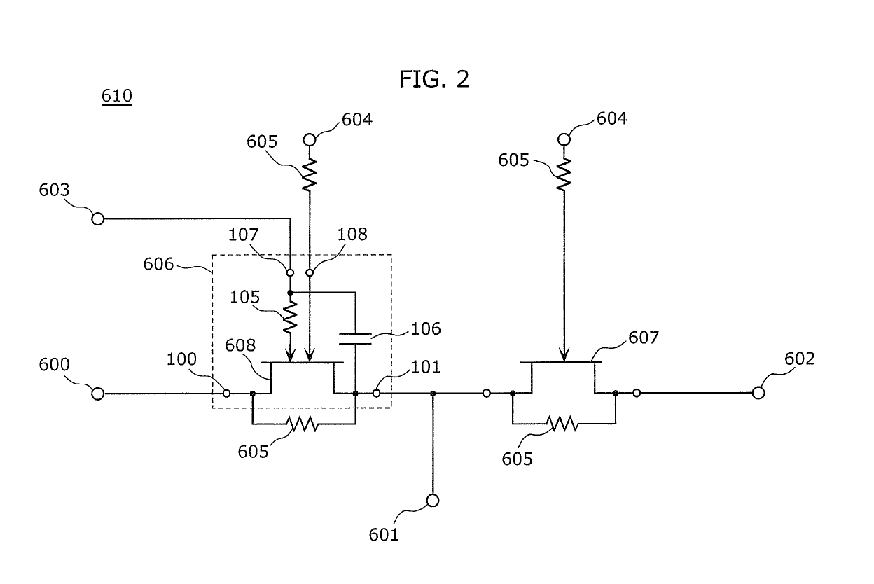

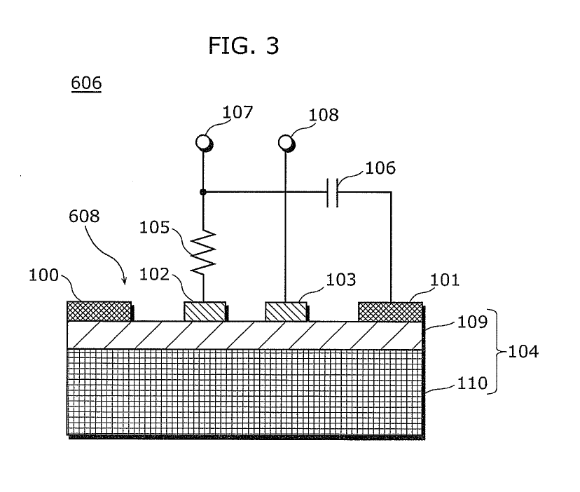

FIG. 2 is a circuit diagram which illustrates, as an example, a configuration of a radio frequency switch 610 according to the present example. FIG. 3 is a sectional view which shows a configuration of the power detection circuit 606 included in the radio frequency switch 610.

The radio frequency switch 610 includes: a power detection circuit 606; an input terminal 600; an input and output terminal 601; an output terminal 602; a power detection terminal 603; a control terminal 604 connected to a control circuit (not-illustrated) of the radio frequency switch 610; plural resistors 605 for fixing potentials; and a switch FET 607.

The power detection circuit 606 is a semiconductor device that detects the power level of an RF signal and includes: a switch FET 608; a resistor 105; a capacitor 106; a power detection terminal 107; and a radio frequency switch control terminal 108. The power detection circuit 606 is loaded into an RF signal path through which an RF signal that has been power-amplified passes; that is, a RF signal path between the input terminal 600 and the input and output terminal 601.

The switch FET 608 is an example of a first FET according to the present invention, and includes: a source electrode 100; a drain electrode 101; a first gate electrode 102; a second gate electrode 103; and a semiconductor substrate 104. The semiconductor substrate 104 includes, for example, a semiconductor layer 109 and an insulative semiconductor layer 110.

The source electrode 100 and the drain electrode 101 are formed on the semiconductor layer 109.

The first gate electrode 102 is formed between the source electrode 100 and the drain electrode 101 and on the semiconductor layer 109, and is in Schottky contact with the semiconductor layer 109

The second gate electrode 103 is formed between the first gate electrode 102 and the drain electrode 101 and on the semiconductor layer 109, and is in Schottky contact with the semiconductor layer 109.

An end of the resistor 105 is electrically connected to the first gate electrode 102 and the other end is electrically connected to the drain electrode 101 via the capacitor 106.

The power detection terminal 107 is electrically connected to a connecting point between the resistor 105 and the capacitor 106, and further electrically connected to the power detection terminal 603.

The radio frequency switch control terminal 108 is electrically connected to the second gate electrode 103 and further electrically connected to the control terminal 604 via the resistor 605 for fixing potentials.

The input terminal 600 is an example of the first terminal according to the present invention, electrically connected to the source electrode 100, and receives an RF signal from the output matching circuit 203.

The output terminal 602 is an example of the second terminal according to the present invention and electrically connected to the drain electrode 101 via the switch FET 607, and through which the RF signal that has been received by the input and output terminal 601 is output. The switch FET 607 is an example of the second FET according to the present invention.

The input and output terminal 601 is an example of the third terminal according to the present invention, electrically connected to the connecting point between the switch FET 607 and the switch FET 608, outputs the RF signal that has been applied to the input terminal 600, and receives the RF signal that has been received by the antenna 206.

The radio frequency switch 610 provided as an example in FIG. 2, for the sake of simplicity, includes: a dual gate FET used as the transmission switch FET 608 having one input terminal and two output terminals; and a single gate FET used as the reception switch FET 607.

It is to be noted that the connection wiring of the resistors 605 for fixing potentials are illustrated by a general connection wiring method, and the connection wiring method of the present invention is not limited to this. In addition, although there is no particular limitation, in the case where the radio frequency switch 610 is used for a multi-mode radio frequency module and includes plural input terminals, for example, the radio frequency switch 610 may include plural power detection circuits 606 each loaded between a corresponding one of the input terminals and the input and output terminal 601 connected to the antenna 206. In the case where there is an RF signal path whose power level does not have to be detected, the power detection circuit 606, by definition, only needs to be provided in a RF signal path in which the power level needs to be detected, even when plural input terminals are included.

In the power detection circuit 606 in FIG. 3, the RF signal amplified by the radio-frequency power amplifier 202 is applied to the source electrode 100 of the switch FET 608, passes through the semiconductor layer 109, and outputs the drain electrode 101. Most of the RF signals provided from the drain electrode 101 are emitted from the antenna 206 connected to a subsequent stage, however, a part of the RF signals is fed back to the first gate electrode 102 via the capacitor 106. The power level and the phase of the RF signal (feedback signal) that is fed back can be adjusted using a resistance value of the resistors 105, a capacitance value of the capacitor 106, and the length of the signal path that connects them.

Furthermore, a potential difference occurs in a Schottky diode formed by the first gate electrode 102 and the semiconductor layer 109 according to a difference in a voltage magnitude and a difference in a phase between the feedback signal and the RF signal which passes through the semiconductor layer 109 immediately under the first gate electrode 102, making it possible to perform a diode detection using a half-wave rectification.

Furthermore, the resistors 105 are included for preventing signal leakage from the semiconductor layer 109 and the capacitor 106 is included for blocking a direct-current voltage and a direct current between the semiconductor layer 109 and the power detection terminal 107, however, the resistors 105 and the capacitor 106 also have function of adjusting the power level and the phase of the feedback signal, as described above.

Furthermore, it is possible to control the depth of a depletion layer immediately under the second gate electrode 103 by applying a control signal to the radio frequency switch control terminal 108, enabling control of conduction and blocking between the source electrode 100 and the drain electrode 101 in the same manner as general radio frequency switches.

It is to be noted that the direct-current potential of the power detection terminal 107 may be higher than the direct-current potential of the source electrode 100. More specifically, a direct-current voltage suitable to a half-wave rectification may be applied arbitrarily to the first gate electrode 102, and although there is no particular limitation, a positive voltage equal to or less than the rise voltage of a Schottky diode formed by the first gate electrode 102 may be applied, for example.

The following provides as an example a result of studying, by running a simulation, an effect obtained by the radio frequency switch 610 according to the present example. It is to be noted that the circuit used for the simulation is the circuit provided as an example in FIG. 2, and the gate width of the switch FETs 607 and 608 is 3 mm, an input power is 20 dBm, and an input frequency is 2 GHz.

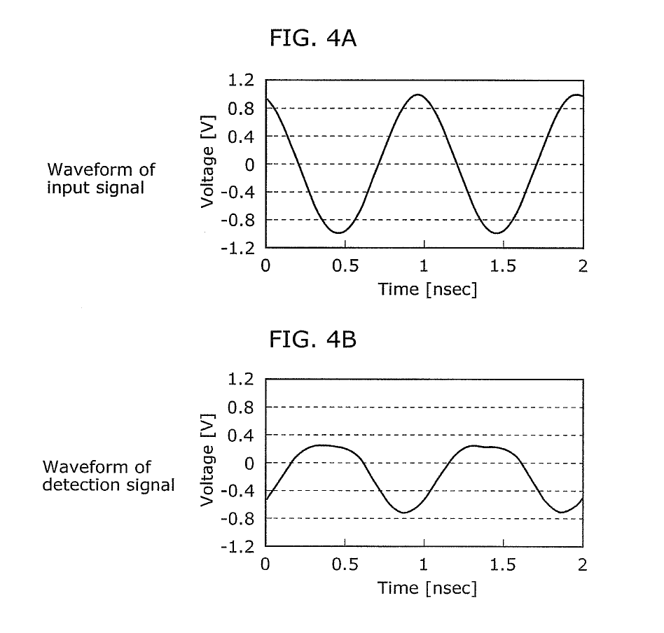

The following first describes a result of a half-wave rectification operation. FIG. 4A and FIG. 4B are diagrams which provide, as examples, simulation results of half-wave rectification operations in the radio frequency switch 610 according to the present example. FIG. 4A shows a waveform of an input signal applied to the input terminal 600 and FIG. 4B shows a waveform of an output signal provided through the power detection terminal 603.

The Schottky diode formed by the gate electrode 102 becomes one of the conduction state and the blocking state according to an applied voltage, and a signal having a voltage waveform that has been half-wave rectified is output as a detection signal to the power detection terminal 107, as exemplified in FIG. 4B. It is possible to detect a signal reflecting the power level using the time integral of the detection signal.

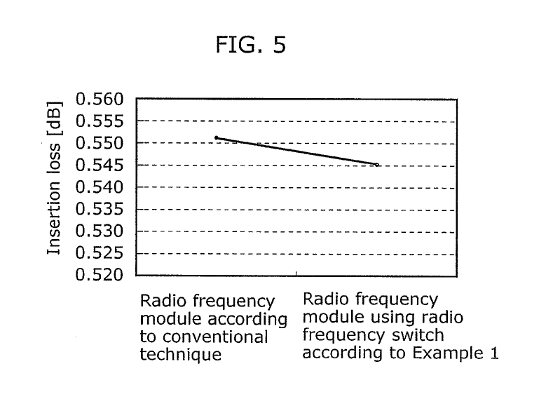

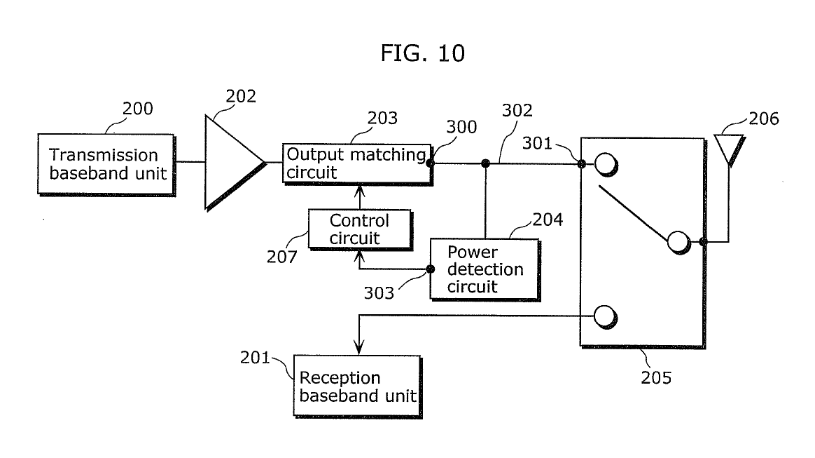

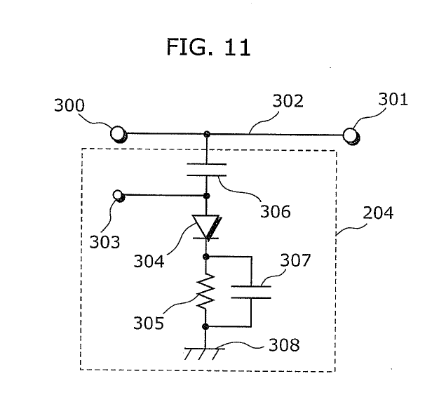

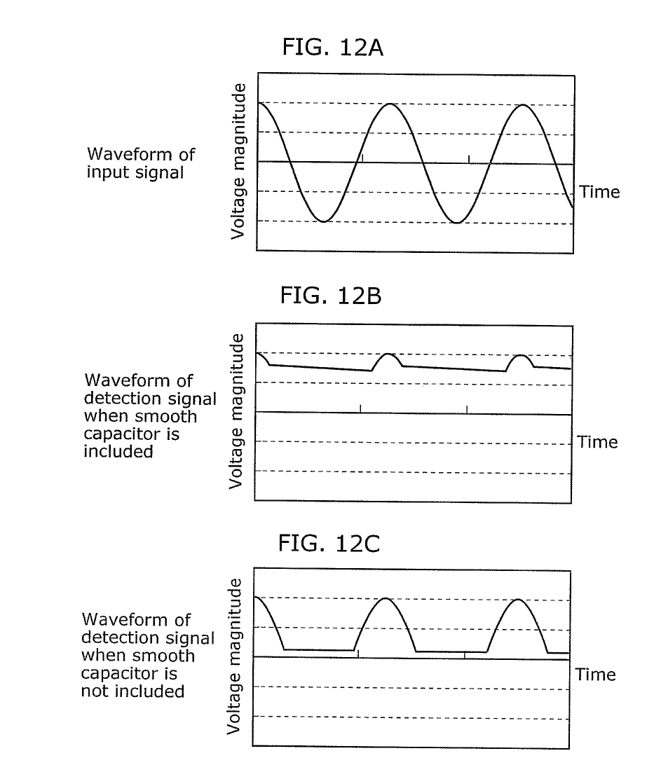

Next, FIG. 5 shows as an example a result of comparing insertion losses of the radio frequency module according to conventional techniques (the radio frequency module in FIG. 10) and the radio frequency module using the radio frequency switch 610 according to the present example (the radio frequency module in FIG. 1).

In the radio frequency module using the radio frequency switch 610 according to the present example, the insertion loss is improved compared to the radio frequency module according to conventional techniques, as exemplified in FIG. 5. In the power detection circuit 606 according to the present example, since the power level is detected by feeding back a part of the radio frequency signals, little or no signal leakage occurs to the earth terminal via the power detection circuit, and thus the insertion loss is improved compared to the radio frequency module according to conventional techniques.

### Example 2

In the present example, description is given centering on points different from Example 1. Other configurations, operations, and effects are the same as Example 1, and thus the description is omitted.

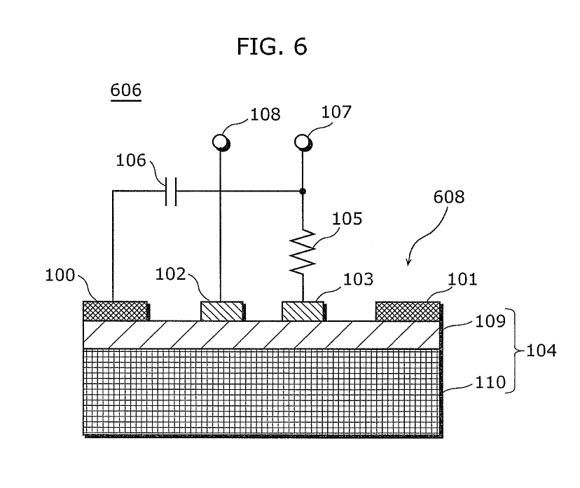

FIG. 6 is a sectional view which shows another configuration of the power detection circuit 606 included in the radio frequency switch 610 according to the present example.

The power detection circuit 606 according to the present example includes: a switch FET 608; a resistor 105; a capacitor 106; a power detection terminal 107; and a radio frequency switch control terminal 108. The switch FET 608 includes: a source electrode 100; a drain electrode 101; a first gate electrode 102; a second gate electrode 103; and a semiconductor substrate 104. The semiconductor substrate 104 includes, for example, a semiconductor layer 109 and an insulative semiconductor layer 110.

An end of the resistor 105 is electrically connected to the second gate electrode 103 and the other end is electrically connected to the source electrode 100 via the capacitor 106.

As opposed to the power detection circuit according to Example 1 in which a part of the RF signals is fed back and a power level is detected by using the signal, an input signal is fed forward in the power detection circuit 606 according to the present example, thereby detecting the power level.

In the power detection circuit 606 in FIG. 6, most of the RF signals that have been amplified by the radio-frequency power amplifier 202 are applied to the source electrode 100, pass through the semiconductor layer 109, and are output through the drain electrode 101. On the other hand, a part of the RF signals that has been amplified by the radio-frequency power amplifier 202 is fed forward to the second gate electrode 103 via the capacitor 106. The power level and a phase of the RF signal (feed forward signal) that is fed forward can be adjusted using a resistance value of the resistor 105, a capacitance value of the capacitor 106, and the length of the signal path that connects them. A potential difference occurs in a Schottky diode formed by the second gate electrode 103 and the semiconductor layer 109, according to a difference in a voltage magnitude and a difference in a phase between the feedback signal and the RF signal which passes through the semiconductor layer 109 immediately under the second gate electrode 103, making it possible to perform a diode detection using a half-wave rectification.

Furthermore, it is possible to control the depth of a depletion layer immediately under the second gate electrode 103 by applying a control signal to the radio frequency switch control terminal 108, enabling control of conduction and blocking between the source electrode 100 and the drain electrode 101 in the same manner as general radio frequency switches.

With the radio frequency module using the radio frequency switch 610 according to the present example, signal leakage to the earth terminal is suppressed, and thus insertion loss is improved, in the same manner as the radio frequency module using the radio frequency switch according to Example 1.

The effects obtained by the radio frequency module using the radio frequency switch 610 according to the present example are similar to the effects obtained by the radio frequency module using the radio frequency switch according to Example 1, however, it is possible to increase flexibility in circuit designing such as the layout of elements and a signal phase adjustment, by arbitrarily selecting between configurations of Example 1 and Example 2.

### Example 3

In Example 3, description is given centering on points different from Example 1. Other configurations, operations, and effects are the same as Example 1, and thus the description is omitted.

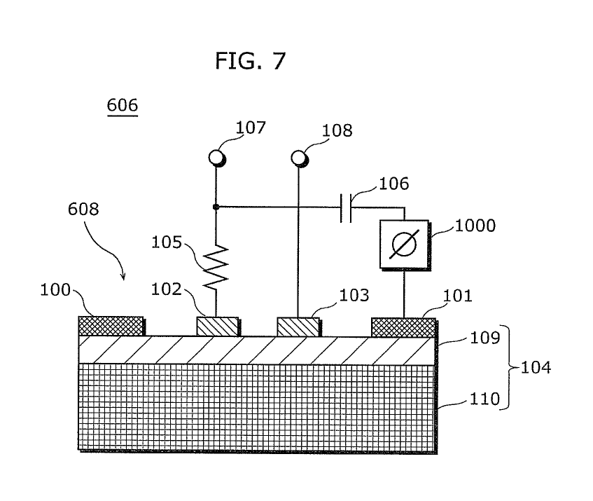

FIG. 7 is a sectional view which shows another configuration of the power detection circuit 606 included in the radio frequency switch 610 according to the present example.

The power detection circuit 606 according to the present example includes: a switch FET 608; a resistor 105; a capacitor 106; a power detection terminal 107; a radio frequency switch control terminal 108; and a phase shifter 1000. The switch FET 608 includes: a source electrode 100; a drain electrode 101; a first gate electrode 102; a second gate electrode 103; and a semiconductor substrate 104. The semiconductor substrate 104 includes, for example, a semiconductor layer 109 and an insulative semiconductor layer 110.

The phase shifter 1000 is inserted between the first gate electrode 102 and the drain electrode 101, and connected in series to the resistor 105 and the capacitor 106.

In the power detection circuit 606 in FIG. 7, the phase of a feedback signal is controlled. More specifically, in the power detection circuit 606 in FIG. 7, a part of the RF signals provided through the drain electrode 101 is fed back to the first gate electrode 102 in the same manner as the power detection circuit according to Example 1. At this time, a harmonic of the feedback signal occurs due to the nonlinearity of current-voltage characteristics of the Schottky diode formed by the first gate electrode 102 and the semiconductor layer 109. In the power detection circuit 606 in FIG. 7, the phase of the feedback signal is appropriately controlled, and the phase of the above-described harmonic component is caused to be approximately reversed phase with respect to the RF signal component that passes through the semiconductor layer 109 immediately under the first gate electrode 102, thereby mutually compensating the harmonic signal components. That means that the power detection circuit 606 in FIG. 7 has a configuration to which a function of lowering distortion characteristics using feedback compensation is added.

The following provides as an example a result of studying, by running a simulation, an effect obtained by the radio frequency switch 610 according to the present example. It is to be noted that the circuit used for the simulation is the circuit provided as an example in FIG. 2, and the gate width of the switch FETs 607 and 608 is 3 mm, an input power is 20 dBm, and an input frequency is 2 GHz.

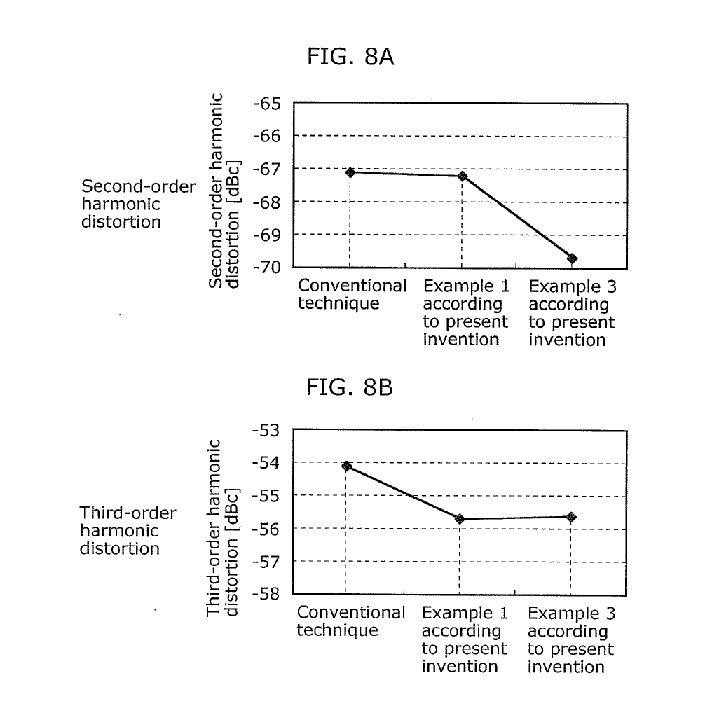

FIG. 8A and FIG. 8B are diagrams which provide simulation results of half-wave rectification operations in the radio frequency switch 610 according to the present example. FIG. 8A is a diagram which shows the second-order harmonic distortion of the radio frequency switch according to conventional techniques and the radio frequency switch according to Examples 1 and 3. FIG. 8B is a diagram which shows the third-order harmonic distortion of the radio frequency switch according to conventional techniques and the radio frequency switch according to Examples 1 and 3

In the radio frequency switch 610 according to the present example as exemplified in FIG. 8B, the second harmonic distortion is improved, compared to the radio frequency switch according to conventional techniques and Example 1, by optimizing the phase of the feedback signal using the phase shifter 1000.

It is to be noted that, in the examples of FIG. 8A and FIG. 8B, the result of adjusting the phase so that the improved amount of the second harmonic distortion becomes maximum is exemplified, however, it is also possible to improve the third harmonic distortion depending on the phase.

Furthermore, the phase shifter 1000 is provided between the drain electrode 101 and the capacitor 106 in FIG. 7, the phase shifter 1000 may be provided between the capacitor 106 and the resistor 105 or between the resistor 105 and the first gate electrode 102.

Furthermore, in the radio frequency switch 610 according to the present example, the type of the phase shifter 1000 is not particularly limited as long as the phase shifter 1000 can adjust the phase of the feedback signal. The phase may be adjusted using the length of the signal path without providing a complicated circuit for controlling the phase, for example.

Furthermore, the radio frequency switch 610 according to the present example may be combined with the radio frequency switch according to Example 2. In such case, the phase shifter 1000 in FIG. 6 is inserted between the second gate electrode 103 and the source electrode 100 and connected in series to the resistor 105 and the capacitor 106. More specifically, the phase shifter 1000 in FIG. 6 is inserted between the source electrode 100 and the capacitor 106, between the capacitor 106 and the resistor 105, or between the resistor 105 and the second gate electrode 103.

### Example 4

In the present example, description is given centering on points different from Example 1. Other configurations, operations, and effects are the same as Example 1, and thus the description is omitted.

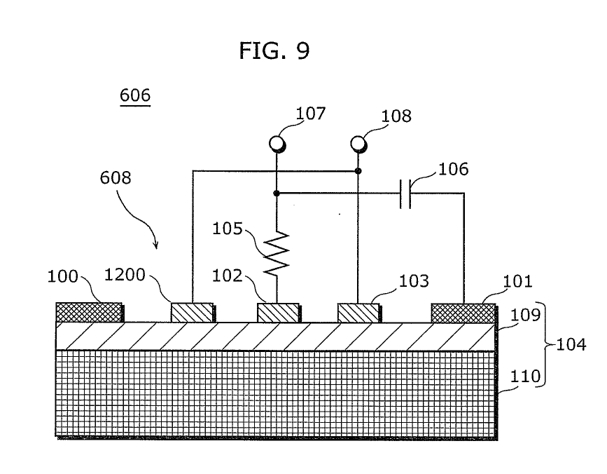

FIG. 9 is a sectional view which shows another configuration of the power detection circuit 606 included in the radio frequency switch 610 according to the present example.

The power detection circuit 606 according to the present example includes: a switch FET 608; a resistor 105; a capacitor 106; a power detection terminal 107; and a radio frequency switch control terminal 108. The switch FET 608 includes: a source electrode 100; a drain electrode 101; a first gate electrode 102; a second gate electrode 103; a semiconductor substrate 104; and a third gate electrode 1200. The semiconductor substrate 104 includes, for example, a semiconductor layer 109 and an insulative semiconductor layer 110.

The third gate electrode 1200 is formed between the source electrode 100 and the first gate electrode 102 and on the semiconductor layer 109, and is in Schottky contact with the semiconductor layer 109. The third gate electrode 1200 and the second gate electrode 103 are electrically connected to the common radio frequency switch control terminal 108.

A multigate FET having plural gate electrodes between the source electrode and the drain electrode is used in many cases as an FET included in the radio frequency switch 610, in view of insertion loss, distortion characteristics, isolation, and a chip size. The power detection circuit 606 according to the present example has the configuration to which such a multiage FET is applied.

The power detection circuit 606 according to the present example has a fundamental operating principle and effects similar to those of the power detection circuit according to Example 1, however, conduction and blocking between the source electrode 100 and the drain electrode 101 are controlled by applying a control signal to the second gate electrode 103 and the third gate electrode 1200.

It is to be noted that a direct-current voltage suitable to half-wave rectification may be arbitrarily applied to the second gate electrode 103 in the same manner as the power detection circuit according to Example 1, and although there is no particular limitation, a positive voltage equal to or less than a rise voltage of the Schottky diode formed by the first gate electrode 102 may be applied, for example. In a multigate FET, in general, the potential between the gate electrodes is unstable, and the potential instability may lead to decrease in operation stability or deterioration in distortion characteristics in some cases. On the other hand, with the power detection circuit 606 according to the present example, additional effects of reforming the potential instability can be expected, by applying the direct-current voltage to the second gate electrode 103.

Furthermore, the second gate electrode 103 and the third gate electrode 1200 are directly wired according to the configuration exemplified in FIG. 9, however, they may be wired via the resistors for fixing potentials.

Furthermore, although the additional effects of the potential instability reform cannot be obtained, the third gate electrode 1200 and the first gate electrode 102 may control conduction and blocking between the source electrode 100 and the drain electrode 101, and a feedback signal may be applied to the second gate electrode 103.

Furthermore, the power detection circuit 606 according to the present example includes the multigate FET having three gate electrodes as the FET included in the radio frequency switch 610, however, the number of the gate electrodes is not limited to three. For example, a fourth gate electrode that is in Schottky contact with the semiconductor layer 109 may further be included between the drain electrode 101 and the second gate electrode 103 and on the semiconductor layer 109.

Furthermore, the radio frequency switch 610 according to the present example may be combined with the radio frequency switch according to Example 2. In such a case, the third gate electrode 1200 is provided between the drain electrode 101 and the second gate electrode 103 and on the semiconductor layer 109, and is in Schottky contact with the semiconductor layer 109 in FIG. 6. In this case, a fourth gate electrode that is in Schottky contact with the semiconductor layer 109 may further be included between the source electrode 100 and the first gate electrode 102 and on the semiconductor layer 109.

The semiconductor device according to the present invention has been described above based on the embodiments, however the present invention is not limited to the embodiments. Other forms in which various modifications apparent to those skilled in the art are included within the scope of the present invention, unless such changes and modifications depart from the scope of the present invention. Furthermore, each component of different embodiments may be arbitrarily combined within the scope of the present invention.

### INDUSTRIAL APPLICABILITY

The present invention is applicable to a semiconductor device, and a radio frequency switch and a radio frequency module using the semiconductor device, and in particular applicable to mobile communication equipment and the like.

What is claimed is:

1. A semiconductor device which detects a power level of a radio-frequency signal, said semiconductor device comprising:
a first FET including:
a semiconductor layer;
a source electrode and a drain electrode that are formed on said semiconductor layer;
a first gate electrode formed between said source electrode and said drain electrode and on said semiconductor layer;
and a second gate electrode formed between said first gate electrode and said drain electrode and on said semiconductor layer, each of said first gate electrode and said second gate electrode being in Schottky contact with said semiconductor layer, and said source electrode receiving the radio-frequency signal;
a resistor having one end electrically connected to said first gate electrode and an other end electrically connected to said drain electrode via a capacitor; and
a power detection terminal electrically connected to a connecting point between said resistor and said capacitor.

2. The semiconductor device according to claim 1, further comprising
a phase shifter inserted between said first gate electrode and said drain electrode and connected to said resistor and said capacitor in series.

3. The semiconductor device according to claim 2, further comprising
a third gate electrode formed between said source electrode and said first gate electrode and on said semiconductor layer, said third gate electrode being in Schottky contact with said semiconductor layer.

4. The semiconductor device according to claim 3, further comprising
a fourth gate electrode formed between said drain electrode and said second gate electrode and on said semiconductor layer, said fourth gate electrode being in Schottky contact with said semiconductor layer.

5. A semiconductor device which detects a power level of a radio-frequency,
said semiconductor device comprising:
a first FET including:
a semiconductor layer;
a source electrode and a drain electrode that are formed on said semiconductor layer;
a first gate electrode formed between said source electrode and said drain electrode and on said semiconductor layer; and
a second gate electrode formed between said first gate electrode and said drain electrode and on said semiconductor layer, each of said first gate electrode and said second gate electrode being in Schottky contact with said semiconductor layer, and said source electrode receiving the radio-frequency signal;
a resistor having one end electrically connected to said second gate electrode and an other end electrically connected to said source electrode via a capacitor; and
a power detection terminal electrically connected to a connecting point between said resistor and said capacitor.

6. The semiconductor device according to claim 5, further comprising
a phase shifter inserted between said second gate electrode and said source electrode and connected to said resistor and said capacitor in series.

7. The semiconductor device according to claim 6, further comprising
a third gate electrode formed between said drain electrode and said second gate electrode and on said semiconductor layer, said third gate electrode being in Schottky contact with said semiconductor layer.

8. The semiconductor device according to claim 7, further comprising
a fourth gate electrode formed between said source electrode and said first gate electrode and on said semiconductor layer, said fourth gate electrode being in Schottky contact with said semiconductor layer.

9. The semiconductor device according to claim 1,
wherein said power detection terminal has a direct-current potential higher than a direct-current potential of said source electrode.

10. The semiconductor device according to claim 5,
wherein said power detection terminal has a direct-current potential higher than a direct-current potential of said source electrode.

11. The semiconductor device according to claim 1, further comprising
a third gate electrode formed between said source electrode and said first gate electrode and on said semiconductor layer, said third gate electrode being in Schottky contact with said semiconductor layer.

12. The semiconductor device according to claim 5, further comprising
a third gate electrode formed between said drain electrode and said second gate electrode and on said semiconductor layer, said third gate electrode being in Schottky contact with said semiconductor layer.

13. A radio frequency switch comprising:
the semiconductor device according to claim 1;
a first terminal electrically connected to said source electrode, through which a radio-frequency signal is input;
a second terminal electrically connected to said drain electrode via a second FET, and through which the radio-frequency signal is output; and
a third terminal electrically connected to a connecting point between said first FET and said second FET, and through which the radio-frequency signal is input and the radio-frequency signal that has been input is output.

14. A radio frequency module comprising:
the radio frequency switch according to claim 13;
an amplifier electrically connected to said first terminal via an output matching circuit, said amplifier supplying said first terminal with a radio-frequency signal that is amplified;
an antenna electrically connected to said second terminal, said antenna transmitting and receiving the radio-frequency signal; and
a control circuit that controls an impedance of said output matching circuit according to a potential of said power detection terminal.
